(19) United States
(12) Patent Application Publication
(10) Pub. No.: US 2005/0142886 A1
(43) Pub. Date: Jun. 30, 2005

(54) Method for forming a contact in semiconductor device

(75) Inventors: Kang Hyun Lee, Yongin-si (KR); Date Gun Lee, Icheon-si (KR); Kee Ho Kim, Seongnam-si (KR)

Correspondence Address: THE LAW OFFICES OF ANDREW D. FORTNEY, PH.D., P.C., 7257 N. MAPLE AVENUE, BLDG. D, 3107, FRESNO, CA, 93720, US

(73) Assignee: DongbuAnam Semiconductor Inc.

(21) Appl. No.: 11/026,288

(22) Filed: Dec. 30, 2004

(30) Foreign Application Priority Data
Dec. 31, 2003 (KR) 10-2003-0101600

(51) Int. Cl. H01L 21/302; H01L 21/461

(52) U.S. Cl. 438/710

(57) ABSTRACT

A method for forming a contact hole in a semiconductor device is disclosed. The method for forming a contact hole in a semiconductor device comprises depositing a nitride layer and an ILD on a substrate including predetermined devices; forming a first photoresist pattern on the ILD and making a via hole by using the first photoresist pattern; performing a first ashing process; forming a second photoresist pattern on the ILD and making a trench using the second photoresist pattern; conducting a PET; performing a second ashing process and etching the predetermined portion of the nitride layer exposed through the via hole; and wet-cleaning the resulting structure. Accordingly, the present disclosure can fabricate a contact hole maximizing the characteristics of a semiconductor device just by performing a Post Etching Treatment after a trench is formed.

### BACKGROUND OF THE INVENTION

1. Field of the Invention

The present disclosure relates generally to semiconductor fabrication and, more particularly, to a method for forming a contact hole by employing a post etching process to remove residues such as polymers after a trench is formed.

2. Background of the Related Art

In recent years, as a design rule for fabricating semiconductor device, especially memory devices, has been directed toward miniaturization, contact holes with a narrow width and a large depth are necessitated. Thus, contact holes for direct contact, word line contact, bit line contact and plate contact should be formed during a fabrication process. Here, the direct contact is to expose the surface of a semiconductor substrate. The word line contact is to expose the upper portion of a gate electrode. However, such contact holes have different depths and various etching target layers.

Different processes are needed to form the contact holes with various depths and etching target layers. The need for different processes may cause cumbersome problems and increase manufacturing cost. Therefore, the contact holes should be preferably made by just one single process. To form the contact holes by just one single process, proper etch rate, selectivity ratio and vertical profile are necessary. The etch rate is defined as etching amount during a given time. The selectivity ratio is the difference of the etching ratio between an etching target layer and a bottom layer having an etching end point. The vertical profile is defined as the width of the bottom of the contact hole formed by etching. However, if the plasma etching process is employed using conventional etching gases such as CH₄ for forming the contact holes by Reactive Ion Etch (hereinafter referred to as “RIE”), a trade-off among etch rate, selectivity ratio and vertical profile will be inevitably entailed. For example, an etching gas including fluorine is primarily used to etching a silicon oxide layer. As the fluorine is getting more added into the etching gas, the etching ratio is increased and the vertical ratio is improved. In contrast, the selectivity ratio is decreased.

FIG. 1a through FIG. 1d are cross-sectional views which schematically illustrate a prior art of forming a contact hole.

Referring to FIG. 1a, a bottom interconnect 11 made of copper is fabricated on a substrate. A nitride layer 12 and an interlayer dielectric layer (hereinafter referred to as “ILD”) 13 are then deposited in sequence. A first photoresist pattern 14 is then formed to make a via hole. Next, a via hole 15 is formed using the first photoresist pattern by performing a first RIE for the IDL.

Referring to FIG. 1b, the first photoresist pattern is removed. Next, an ashing process is then employed to remove the residues such as polymers 16a arising from the first RIE.

Referring to FIG. 1c, a second photoresist pattern 17 is formed to make a trench on the substrate having the via hole. Next, a trench 18 is formed using the second photoresist pattern by performing a second RIE for the IDL. Residues such as polymers 16b may be caused by the second RIE.

Referring to FIG. 1d, the resulting structure is cleaned by the ashing process. An etching process 19 is employed for the nitride layer 12 and the bottom interconnect is exposed. Next, the wet cleaning process is performed for the resulting structure.

The conventional method removes the residues such as polymers using the ashing process. However, residues such as polymers may be hardly removed by the ashing process. Moreover, residues may be caused after the nitride is etched. Therefore, such residues may deteriorate the flatness of the bottom interconnect and the contact resistance.

U.S. Pat. No. 6,589,883, Gole et al., discloses a post-etch treatment for enhancing and stabilizing the photoluminescence (PL) from a porous silicon (PS) substrate.

U.S. Pat. No. 5,817,579, Ko et al., discloses a method for forming a via through a silicon oxide layer.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIGS. 1a through 1d are cross-sectional views which schematically illustrate a prior art of forming a contact hole.

FIGS. 2a through 2d are cross-sectional views which schematically illustrate an example process for forming a contact hole according to the present invention.

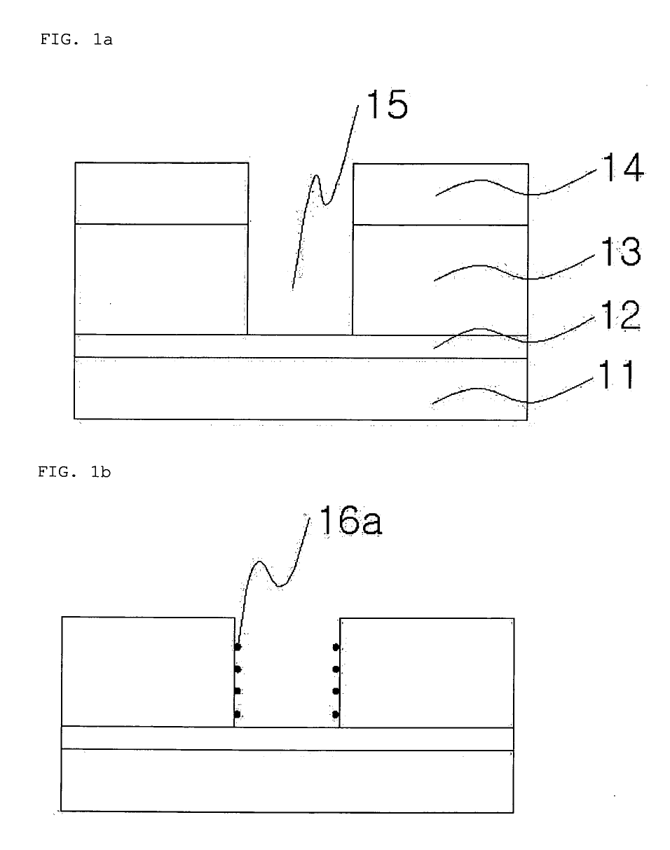

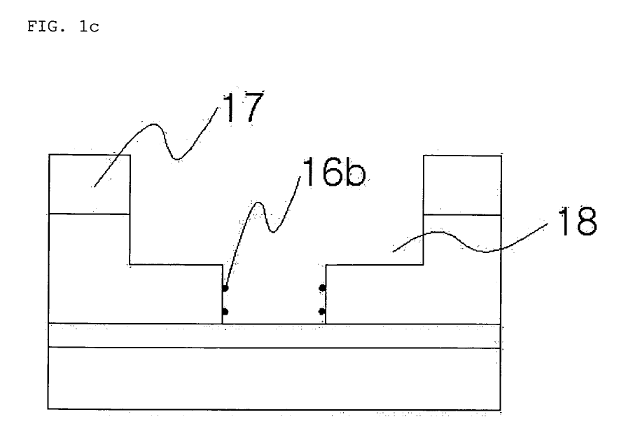

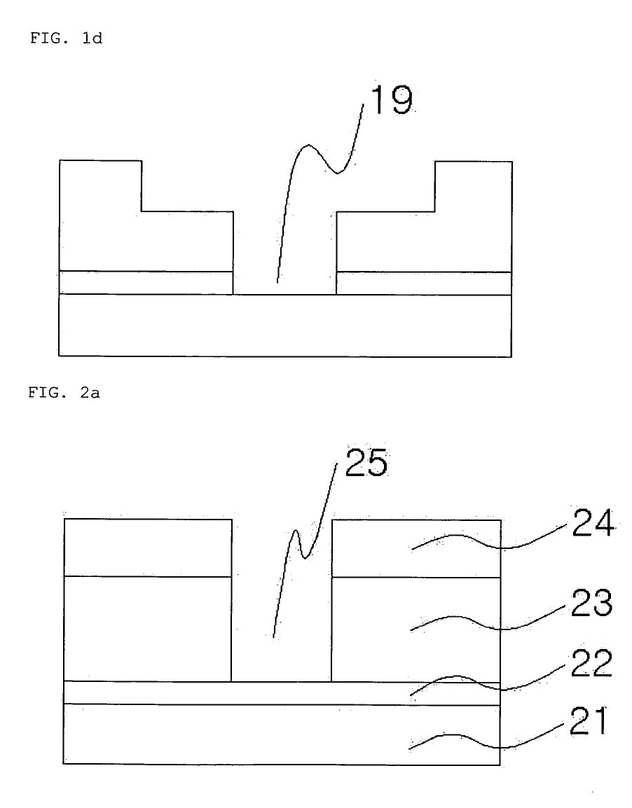

### DETAILED DESCRIPTION OF THE PREFERRED EMBODIMENT

The present invention is directed to a method for forming contact holes in a semiconductor device that obviates one or more problems due to limitations and disadvantages of the related art.

An object of the present disclosure is to fabricate a contact hole maximizing the characteristics of a semiconductor device just by performing a Post Etching Treatment (hereinafter referred to as “PET”) after a trench is formed.

To achieve the object and other advantages of and in accordance with the purpose of the invention, as embodied and broadly described herein, an method for forming a contact hole in a semiconductor device according to the present invention comprises depositing a nitride layer and an ILD on a substrate including predetermined devices; forming a first photoresist pattern on the ILD and making a via hole by using the first photoresist pattern; performing a first ashing process; forming a second photoresist pattern on the ILD and making a trench using the second photoresist pattern; conducting a PET; performing a second ashing process and etching the predetermined portion of the nitride layer exposed through the via hole; and wet-cleaning the resulting structure.

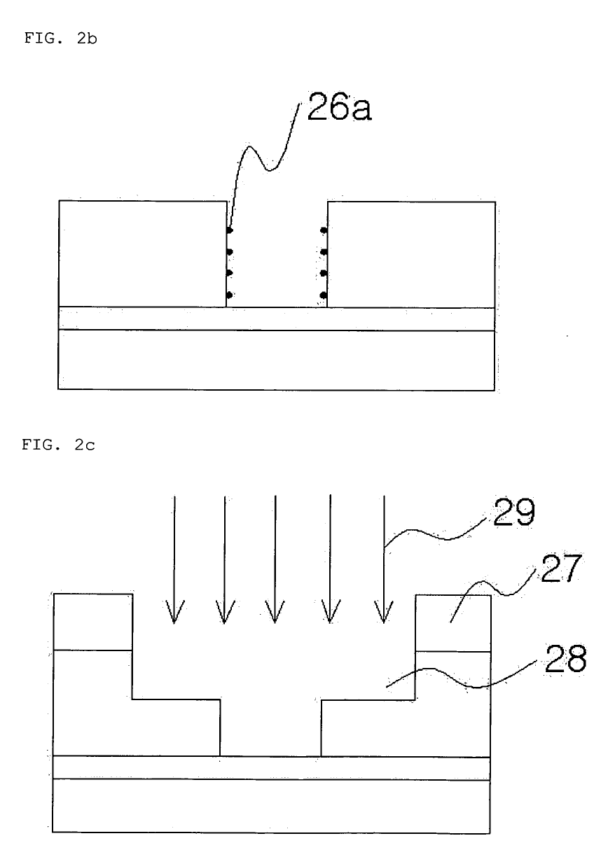

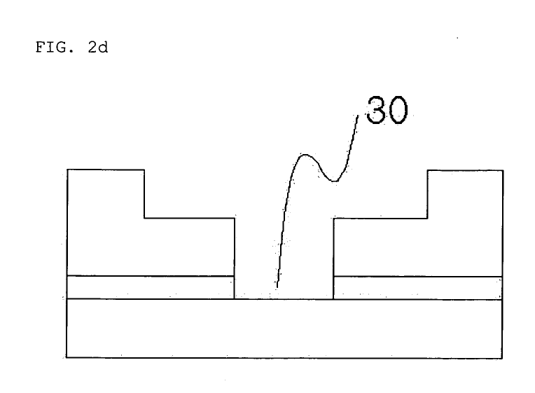

FIGS. 2a through 2e are cross-sectional views illustrating an example process of forming a contact hole according to the present invention.

Referring to FIG. 2a, a nitride layer 22 and an ILD 23 are deposited on the substrate including predetermined devices. A first photoresist pattern 24 is then formed on the ILD 23. In detail, a bottom interconnect layer 21 is fabricated on a substrate. The bottom interconnect layer 21 is made of a conductive material such as copper. A nitride layer 22 and ILD 23 are deposited on the resulting structure. A first photoresist pattern 24 is formed to make a via hole. A first RIE for the ILD 23 is performed to form the via hole. The nitride layer 22 is preferably made of silicon nitride. The ILD 23 is preferably made of a material selected from the group of Borosilicate Glass (hereinafter referred to as “BSG”), Fluorinated Silica Glass (hereinafter referred to as “FSG”), Phospho-Silicate Glass referred to as “PSG”), and Boron Phosophorus Spin-On-Glass (hereinafter referred to as “BPSG”).

Referring to FIG. 2b, a first ashing process is applied to the resulting structure. In particular, the first ashing process is performed to remove the first photoresist pattern and residues such as polymers 26a arising from the first RIE. However, because of the large aspect ratio of the via hole, the first ashing process may hardly remove the residues such as polymers 26a remaining on the inside wall of the via hole 25. The ashing process preferably comprises the dry-removing or wet-removing of the photoresist pattern formed by dry-etching, wet-etching, or ion implantation.

Referring to FIG. 2c, a second pattern 27 is formed on the ILD. A trench 28 is formed using the second pattern. A PET is performed for the resulting structure. As shown in FIG. 2c, the second photoresist pattern 27 is formed on the resulting structure. A trench 28 is formed using the second photoresist pattern by performing a second RIE for the ILD 23. The PET 29 is then performed to remove residues such as polymers. Although the PET employs O₂ and plasma to remove the residues, the PET does not influence on the profile of the ILD because the PET does not etch any portion of the ILD.

Referring to FIG. 2d, an ashing process is performed for the resulting substrate. The predetermined portion of the nitride layer exposed through the via hole is etched. The resulting structure is then wet-cleaned. In detail, the ashing process is employed for cleaning the resulting structure after the trench is formed. An etching process 30 is then performed to expose the bottom interconnect. The resulting structure is then wet-cleaned. Finally, the contact hole is completed.

Accordingly, the present disclosure can fabricate a contact hole maximizing the characteristics of a semiconductor device just by performing a single process of a PET after a trench is formed.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

1. A method for forming a contact hole in a semiconductor device comprising:
depositing a nitride layer and an ILD on a substrate including predetermined devices;
forming a first photoresist pattern on the ILD and making a via hole by using the first photoresist pattern;
performing a first ashing process;
forming a second photoresist pattern on the ILD and making a trench using the second photoresist pattern;
conducting a PET;
performing a second ashing process and etching the predetermined portion of the nitride layer exposed through the via hole; and
wet-cleaning the resulting structure.

2. The method as defined by claim 1, wherein the ILD is made of one selected from the group consisting of BSG, FSG, PSG, and BPSG.

3. The method as defined by claim 1, wherein the PET employs the O₂ and plasma.
